(19) United States
(12) Patent Application Publication
(10) Pub. No.: US 2016/0160388 A1
(43) Pub. Date: Jun. 9, 2016

(54) SILICON SINGLE CRYSTAL INGOT AND WAFER FOR SEMICONDUCTOR

(71) Applicant: LG SILTRON INC., Gyeongsangbuk-do (KR)

(72) Inventors: Young Ho HONG, Gyeongsangbuk-do (KR); Hyun Woo PARK, Gyeongsangbuk-do (KR)

(21) Appl. No.: 14/891,035

(22) PCT Filed: Jan. 23, 2014
(86) PCT No.: PCT/KR2014/000653

§ 371 Date: Feb. 17, 2016

(30) Foreign Application Priority Data
May 21, 2013 (KR) 10-2013-0056958

(51) Int. Cl. C30B 29/06; H01L 29/30; C30B 30/04; C30B 11/02; C30B 11/00

(52) U.S. Cl. CPC C30B 29/06; C30B 11/02; C30B 11/006; C30B 11/003; C30B 30/04; H01L 29/30

(57) ABSTRACT

A silicon single crystal ingot and a wafer for a semiconductor in one embodiment include a transition region which dominantly has a crystalline defect having a size of 10 nm to 30 nm among the crystalline defects included in an interstitial dominant defect-free region. The difference between the initial oxygen concentration before performing at least one heat treatment to the ingot and the wafer and the final oxygen concentration after performing at least one heat treatment is 0.5 ppma or less.

### TECHNICAL FIELD

The embodiment relates to a silicon single crystal ingot and wafer for semiconductors and an apparatus for growing the ingot.

### BACKGROUND ART

In general, as methods for manufacturing silicon wafers, a Floating Zone (FZ) method or a CZochralski (CZ) method is mainly used. If a silicon single crystal ingot is grown using the FZ method, it is difficult to manufacture a silicon wafer having a large diameter and process costs are very high and, thus, a silicon single crystal ingot is generally grown based on the CZ method.

According to the CZ method, polycrystalline silicon is charged into a quartz crucible, a graphite heating element is heated, and then the charged polycrystalline silicon is melted by using the heated graphite heating element. And then, a seed crystal is submerged in the resultant molten liquid silicon acquired as a result of melting, and crystallization is carried out at the interface of the molten liquid silicon so that the seed crystal is rotated and pulled, thus growing a silicon single crystal ingot. Thereafter, the grown silicon single crystal ingot is sliced, etched, and polished, thereby producing wafers.

FIG. 1 is a view schematically illustrating a distribution of crystal defect regions according to V/G when a silicon single crystal ingot is grown. Here, V represents a pulling velocity of a silicon single crystal ingot and G represents a vertical temperature gradient around a solid-liquid interface.

According to Voronkov theory, if a silicon single crystal ingot having V/G of a designated critical value or more is pulled at a high speed, the silicon single crystal ingot is grown in a region which is rich in vacancies causing void-based defects (hereinafter, referred to as a ‘V region’). That is, the V region is a region in which there is an excess of vacancies due to insufficiency of silicon atoms.

Further, if a silicon single crystal ingot is pulled at V/G of less than the designated critical value, the silicon single crystal ingot is grown in an O band region including Oxidation Induced Stacking Faults (OSFs).

Further, if a silicon single crystal ingot of lower V/G is pulled at a low speed, the silicon single crystal ingot is grown in an interstitial region caused by an electrical potential loop in which silicon between lattices is gathered (hereinafter, referred to as an ‘I region’). That is, the I region is a region in which there are many aggregates of silicon between lattices due to excess silicon atoms.

A vacancy dominant defect-free region in which vacancies are dominant (hereinafter, referred to as a ‘VDP’ region) and an interstitial dominant defect-free region in which interstitials are dominant (hereinafter, referred to as an ‘IDP’ region) are present between the V region and the I region. The VDP region and the IDP region are the same in that silicon atoms are not insufficient or not excessive but differ from each other in that the concentration of excess vacancies is dominant in the VDP region and the concentration of excess interstitials is dominant in the IDP region.

A small void region which belongs to the O band region and has fine vacancy defects, for example, Direct Surface Oxide Defects (DSODs), may be present. Here, in order to grow a single crystal ingot in the VDP region and the IDP region, corresponding V/G needs to be maintained during growth of the silicon single crystal ingot.

If heat treatment of a defect-free wafer, manufactured by the above-described process, is repeated, a leakage problem due to oxygen precipitates may be issued. For example, when the defect-free wafer is a wafer for Silicon On Insulators (SOI), oxygen precipitates increase as severe heat treatment is repeatedly carried out, resulting in product failure and sub leakage.

### DISCLOSURE

### Technical Problem

An object of the embodiment is to provide a silicon single crystal ingot and wafer for semiconductors, where the generation of oxygen precipitates due to heat treatment may be suppressed and an apparatus for growing the ingot.

### Technical Solution

In one embodiment of the present invention, a silicon single crystal ingot and wafer for semiconductors includes a transition region which dominantly has crystal defects having a size of 10 nm to 30 nm, among crystal defects included in an interstitial dominant defect-free region, wherein a difference between an initial oxygen concentration before heat treatment of the ingot and wafer is executed at least one time and a final oxygen concentration after heat treatment of the ingot and wafer has been executed at least one time is 0.5 ppma or less.

The transition region may further include a vacancy dominant defect-free region, and the interstitial dominant defect-free region may occupy 70% or more of the entire transition region based on the diameter of the wafer.

Among crystal defects included in the transition region, the crystal defects having a size of 10 nm to 30 nm may be more than 50%. Among entire crystal defects included in the transition region, the crystal defects having a size of 10 nm to 30 nm may be more than 70%. The size of the crystal defects included in the transition region may be 10 nm to 19 nm.

The vacancy dominant defect-free region and the interstitial dominant defect-free region may be divisible by a Ni haze method.

The execution of heat treatment at least one time may include repetition of heat treatment 6 times or more.

The wafer may be a wafer for SOI.

The initial oxygen concentration may be 10 ppma or less.

The transition region may include crystal defects, belonging to an O band region, at an amount of 30% or less or may not include the crystal defects belonging to the O band region.

The transition region may further include an O band region and a vacancy dominant defect-free region, and the o band and vacancy dominant defect-free regions may occupy less than 30% of the entire transition region based on a diameter of the wafer.

The vacancy dominant defect-free region may be located at an edge of the wafer, and the interstitial dominant defect-free region may be located at a center inside the edge of the wafer.

A single crystal ingot growing apparatus for growing the silicon single crystal ingot may include a crucible containing a molten liquid silicon; a heater heating the crucible; a magnetic field applying unit applying a magnetic field to the crucible; and a controller controlling the heater and the magnetic field applying unit, to locate a MGP at a position lower than a position of a maximum heating part by 20% to 40% based on an interface of the molten liquid silicon.

### Advantageous Effects

An silicon single crystal ingot and wafer for semiconductors and an apparatus for growing the ingot in accordance with one embodiment dominantly has crystal defects having a size of 10 nm to 30 nm, among crystal defects included in an IDP region, and an oxygen concentration difference ΔOi of 0.5 ppma or less and, thus, even if heat treatment of the wafer is subsequently executed, generation of oxygen precipitates may be suppressed so that the product failure and incurrence of sub leakage may be controlled.

### DESCRIPTION OF DRAWINGS

FIG. 1 is a view schematically illustrating a distribution of crystal defect regions according to V/G when a silicon single crystal ingot is grown.

FIG. 2 is a view illustrating a single crystal ingot growing apparatus in accordance with one embodiment.

FIG. 3 is a view illustrating growth rates of a silicon single crystal ingot for semiconductors and a distribution of crystal defects in accordance with one embodiment.

FIG. 4 is a plan view of a silicon single crystal wafer for semiconductors in accordance with one embodiment.

FIG. 5 is a plan view of a high-quality silicon single crystal wafer for semiconductors in accordance with another embodiment.

FIG. 6 illustrates cross-sectional views of a general process for manufacturing a wafer for SOI.

FIG. 7a is a graph representing initial oxygen concentrations of silicon wafers, FIG. 7b is a graph representing final oxygen concentrations of silicon wafers after heat treatment is repeated 6 times at a temperature of 1,000° C. for 1 hour, and FIG. 7c is a view illustrating GOI after heat treatment has been executed.

FIG. 8 is a flowchart illustrating a Ni haze method for dividing defect regions of a silicon single crystal wafer in accordance with one embodiment.

FIG. 9 is a view illustrating two-stage heat treatment.

FIG. 10 is a view illustrating metal precipitates.

FIG. 11 is a view illustrating protrusions formed by etching.

FIG. 12 is a view illustrating defect hazes according to Ni contamination concentrations.

FIG. 13a is a view illustrating a surface state of a silicon single crystal wafer if Cu contamination is used and FIG. 13b is a view illustrating a surface state of a silicon single crystal wafer if Ni contamination is used.

FIG. 14 is a table illustrating test results of the optimum conditions of two-stage heat treatment.

FIGS. 15a to 15c are views illustrating distributions of defects according to oxygen concentrations based on Cu.

FIGS. 16a to 16c are views illustrating distributions of defects according to oxygen concentrations based on Ni.

FIG. 17a is a view illustrating division of regions defined in a silicon single crystal wafer through Cu-based defect detection, and FIG. 17b is a view illustrating division of regions defined in a silicon single crystal wafer through Ni-based defect detection in accordance with one embodiment.

### BEST MODE

Reference will now be made in detail to the preferred embodiments of the present invention, examples of which are illustrated in the accompanying drawings. However, the embodiments may be variously modified and do not limit the scope of the present invention. The embodiments of the present invention are provided only to more completely describe the preset invention to those skilled in the art.

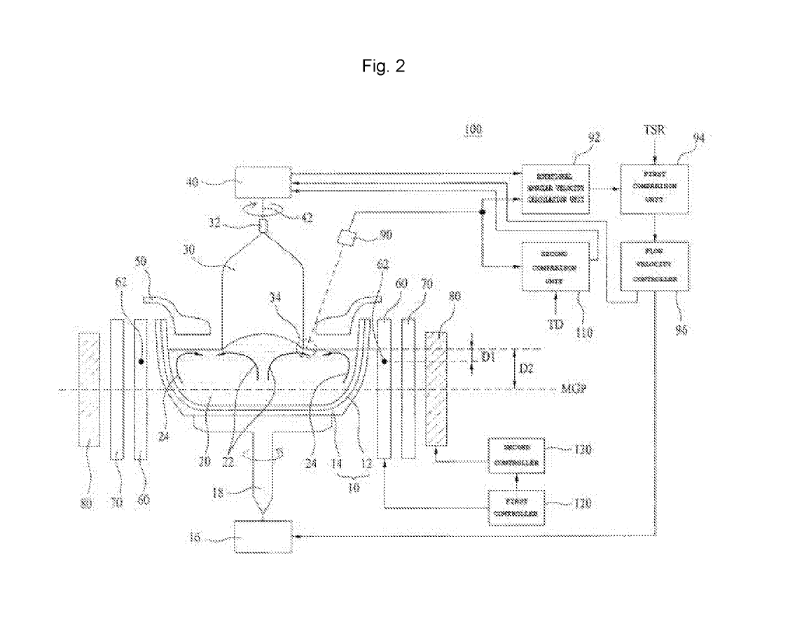

FIG. 2 is a view illustrating a single crystal ingot growing apparatus 100 in accordance with one embodiment.

The single crystal ingot growing apparatus 100 shown in FIG. 2 includes a crucible 10, a support shaft driving unit 16, a support rotary shaft 18, a molten liquid silicon 20, an ingot 30, a seed crystal 32, a wire pulling unit 40, a pulling wire 42, a heat shielding member 50, a heater 60 disposed around the crucible 10, a heat insulator 70, a magnetic field applying unit 80, a diameter sensor unit 90, a rotational angular velocity calculation unit 92, a first comparison unit 94, a flow velocity controller 96, a second comparison unit 110, and first and second controllers 120 and 130.

With reference to FIG. 2, the silicon single crystal ingot growing apparatus 100 according to the embodiments the silicon single crystal ingot 30 using the CZ method as below.

First, a high purity polycrystalline material of silicon in the crucible 10 is heated to a temperature of a melting point or higher by the heater 60 and is thus melted to be the molten liquid silicon 20. Here, the crucible 10 containing the molten liquid silicon 20 has a dual structure in which the inner surface of the crucible 10 is formed of quartz 12 and the outer surface of the crucible 10 is formed of graphite 14.

Thereafter, the pulling unit 40 unwinds the pulling wire 42 so that the front end of the seed crystal 32 contacts or is immersed in the approximately central position of the surface of the molten liquid silicon 20. Here, the silicon seed crystal 32 may be held in place using a seed chuck (not shown).

Thereafter, the support shaft driving unit 16 rotates the support rotary shaft 18 of the crucible 20 in a direction shown by an arrow and, simultaneously, the pulling unit 40 rotates the ingot 30 by the pulling wire 42 and thus pulls and grows the ingot 30. Here, by adjusting a pulling velocity V of the ingot 30 and a temperature gradient G, ΔG, the silicon single crystal ingot 30 of a cylindrical shape may be completed.

The heat shielding member 50 is disposed between the silicon single crystal ingot 30 and the crucible 10 so as to surround the ingot 30 and serves to block heat radiated from the ingot 30.

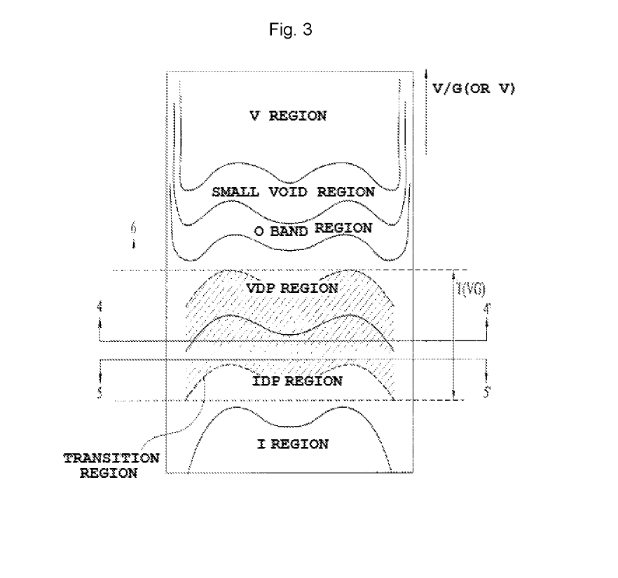

FIG. 3 is a view illustrating growth rates of a silicon single crystal ingot for semiconductors and a distribution of crystal defects in accordance with one embodiment.

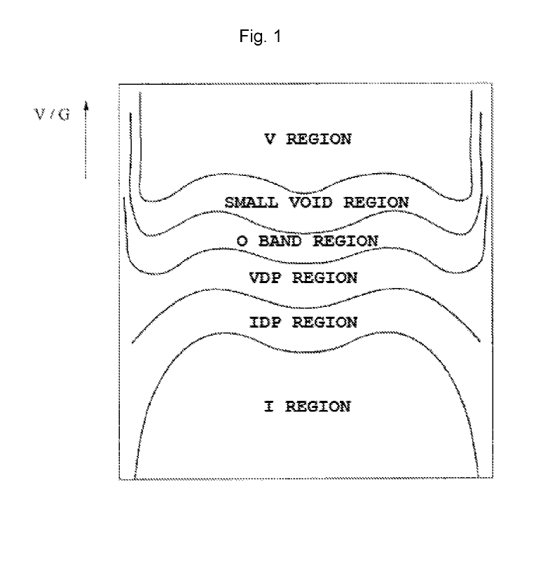

The distribution of defects of the silicon single crystal ingot shown in FIG. 3 is the same as the distribution of defects of the silicon single crystal ingot shown in FIG. 1 except that a transition region is further defined. Therefore, a detailed description of a V region, a small void region, an O band region, a VDP region, an IDP region, and an I region will thus be omitted. Here, the transition region is defined as a region which dominantly has crystal defects having a size of 10 nm to 30 nm, among crystal defects included in the VDP region. A dominant degree may mean 50% or more. That is, among entire crystal defects included in the transition region, crystal defects having a size of 10 nm to 30 nm may occupy 50% or more. Otherwise, among entire crystal defects included in the transition region, crystal defects having a size of 10 nm to 30 nm may occupy 70% or more.

For example, the size of crystal defects dominantly included in the transition region may be 10 nm to 19 nm. Such a transition region may not include crystal defects included in a ring-shaped oxide organic stacked bonding region, i.e., the O band region, or the I region, but the embodiments are not limited thereto.

If the apparatus shown in FIG. 2 grows the ingot 30 at arbitrary V/G selected within a target V/G range shown in FIG. 3 (hereinafter, referred to as ‘T(VG)’), the ingot 30 or a silicon wafer in accordance with this embodiment may dominantly have crystal defects having a size of 10 nm to 30 nm.

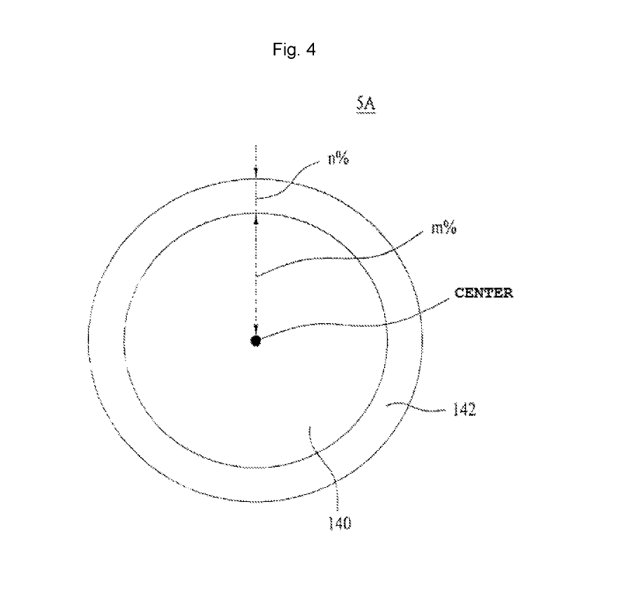

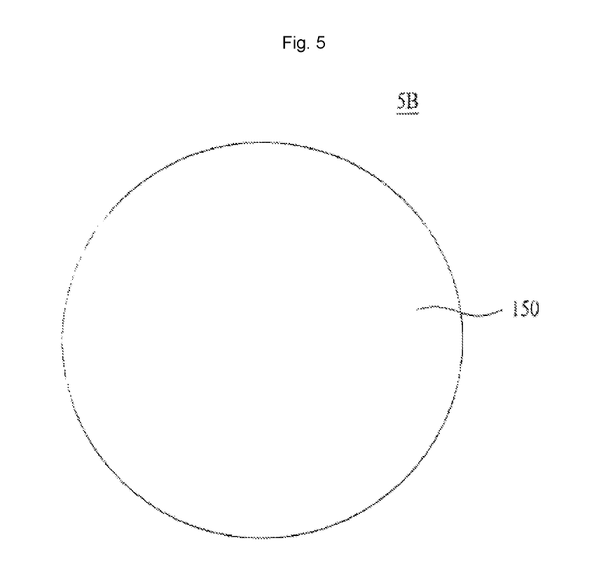

FIG. 4 is a plan view of a silicon single crystal wafer 5A for semiconductors in accordance with one embodiment and FIG. 5 is a plan view of a high-quality silicon single crystal wafer 5B for semiconductors in accordance with another embodiment.

When the ingot 30 is grown at a V/G value of 4-4′ within the T(V/G) shown in FIG. 3, the silicon wafer 5A may have a crystal defect distribution as shown in FIG. 4. In this case, a transition region of the silicon wafer 5A is distributed over an IDP region 140 and a VDP region 142.

Otherwise, when the ingot 30 is grown at a V/G value of 5-5′ within the T(V/G) shown in FIG. 3, the silicon wafer 5B may have a crystal defect distribution as shown in FIG. 5. In this case, a transition region of the silicon wafer 5B is distributed only over an IDP region 150. That is, the transition region of the silicon wafer 5B is not distributed over a VDP region.

Consequently, in the silicon wafer in accordance with this embodiment, the IDP region may occupy m % of the entire transition region, as stated in Equation 1 below, and the VDP region may occupy n % of the entirety of the transition region, as stated in Equation 2 below.

m=100x Equation 1

n=100(1−x) Equation 2

Here, 0.7≦x≦1. That is, the IDP region may occupy 70% or more of the entire transition region and the O band and VDP regions may occupy less than 30% of the entire transition region based on the diameter of the silicon wafer. Here, in the silicon wafer 5A formed in the transition region, as exemplarily shown in FIG. 4, the VDP region may be located at the edge of the silicon wafer 5A and the IDP region may be located at the center inside the edge of the silicon wafer 5A. Differently from FIG. 4, in the transition region, the IDP region may be located at the edge of the silicon wafer and the VDP region may be located at the center inside the edge of the silicon wafer. However, the disclosure is not limited thereto but, in the transition region of the silicon wafer, the VDP region and the IDP region may take various shapes.

The above-described silicon wafer may be variously used according to purposes. If heat treatment of such a silicon wafer is subsequently carried out, oxygen precipitates may be generated. The oxygen precipitates relate to an initial oxygen concentration of silicon wafer but also relate to vacancies providing sites. When the same initial oxygen concentration is given, oxygen precipitates is more generated in the VDP region than in the IDP region. For example, a process for manufacturing a wafer for Silicon On Insulators (SOI) using a silicon wafer will be described below.

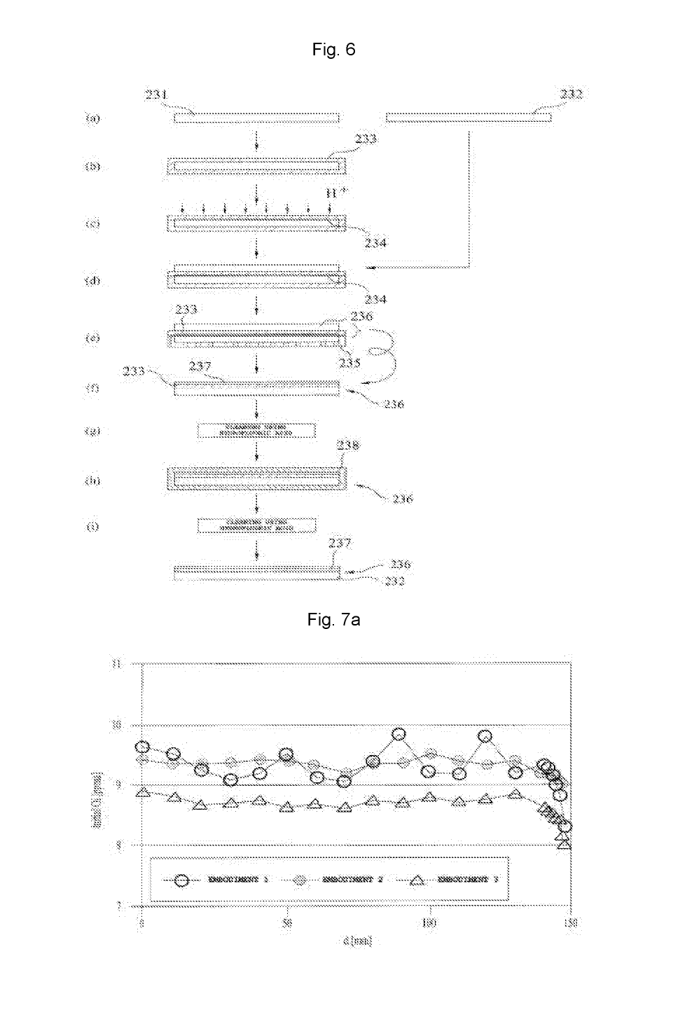

FIG. 6 illustrates general cross-sectional views of a process for manufacturing a wafer for SOI.

First, in initial operation (a), a bond wafer 231 serving as a silicon active layer and a base wafer 232 serving as a support substrate are prepared. Here, the bond wafer 231 and/or the base wafer 232 may correspond to silicon wafers having a transition region grown by the above-described Czochralski method. That is, a silicon wafer may be manufactured from a single crystal ingot grown with controlling V/G using the single crystal ingot growing apparatus 100 shown in FIG. 2.

Thereafter, in operation (b), the surface of at least one of the bond wafer 231 or the base wafer 232 is oxidized. Here, the bond wafer 231 is thermally oxidized, thus forming an oxide film 233 on the surface thereof. The oxide film 233 may have a thickness of maintaining insulation properties or have an excessively thin thickness of 10 nm to 100 nm.

In operation (c), ions, such as hydrogen, helium or argon, are implanted into one side surface of the bond wafer 231 having the oxide film 233 on the surface thereof, thus forming an ion implantation layer 234 (or a cleavage region).

In operation (d), after the bond wafer 231, into which the ions are implanted, is cleaned, the surface of the bond wafer 231, into which the ions are implanted, and the surface of the base wafer 232 are bonded by the oxide film (insulating film) 233. For example, the two wafers 231 and 232 may be bonded to each other without an adhesive and the like by surface contact between the two wafers 231 and 232 at a room temperature under a clean atmosphere. Further, an insulating wafer formed of SiO₂, SiC, Al₂O₃ and the like may be used as the base wafer 232. In this case, the bond wafer 231 and the base wafer 232 may be directly bonded without the oxide film 233.

Thereafter, in operation (e), a part of the bond wafer 231 is separated from the ion implantation layer 234 by heat treatment. That is, the cleavage region 234 of the bond wafer 231 is cut horizontally and a thin layer is separated from the base wafer 232. For example, when heat treatment at a temperature of about 500° C. or more is applied to the bond wafer 231 and the base wafer 232, which are bonded to each other, under the inert gas atmosphere, the bond wafer 231 and the base wafer 232 may be separated into a peeled wafer 235 and a wafer for SOI 236 [a silicon active layer 237+the oxide film 233+the base wafer 232] by rearrangement of crystals and coalescence of air bubbles. Here, the peeled wafer 235 which is incidentally produced may be reused as the base wafer 232 or the bond wafer 231 by executing recycling, such as polishing, on the peeled surface of the peeled wafer 235.

In operation (f), heat treatment for bonding is applied to the wafer for SOI 236. Since bonding force of the wafers, adhered to each other by the bonding operation or the peeling off heat treatment the operations (d) and (e), is too weak to be directly used in a device manufacturing process and, in the operation (f), heat treatment at a high temperature is applied to the wafer for SOI 236 as heat treatment for bonding, thus sufficiently increasing bonding strength. For example, such heat treatment may be executed at a temperature of 1050° C. to 1200° C. for 30 minutes to 2 hours under the inert gas atmosphere.

In operation (g), the oxide film formed on the surface of the wafer for SOI 236 is removed by cleaning using hydrofluoric acid.

In operation (h), as needed, oxidation to adjust the thickness of the silicon layer 237 is executed, and, in operation (l), so-called sacrificial oxidation is executed to remove the oxide film 238 by cleaning using hydrofluoric acid.

When a wafer for SOI is manufactured through the above-described operations (a)˜(l), after the operation (b), a refresh operation may be executed 6 times or more, poly-silicon stacked heat treatment may be executed 16 times, and nitride stacked heat treatment may be executed 16 times, thus generating defects and sub leakage of the wafer for SOI. That is, as the number of repetitions of heat treatment of the silicon wafer increases and as the structure of the silicon wafer become more complex, influence on a product for SOI by oxygen precipitates increases. However, since the silicon wafer in accordance with the embodiment has an oxygen concentration difference ΔOi of 0.5 ppma or less, generation of oxygen precipitates may be controlled. Here, the oxygen concentration difference ΔOi means at least a difference between an initial oxygen concentration prior to heat treatment and a final oxygen concentration after heat treatment. The initial oxygen concentration and the final oxygen concentration are not displayed as in the defect regions, as exemplarily shown in FIG. 3, but mean oxygen concentrations of the entirety of a wafer or an ingot.

As the oxygen concentration difference ΔOi increases, a large amount of oxygen precipitates are formed. In consideration of this fact, if the oxygen concentration difference ΔOi is 0.5 ppma or less, as in the embodiment, although heat treatment is repeated 6 times or more, generation of oxygen precipitates may be suppressed and, thus, generation of product failure and leakage current may be controlled. Here, the initial oxygen concentration and the final oxygen concentration are different from those of the O band shown in FIG. 3. If the silicon wafer has the above-described oxygen concentration difference ΔOi, the O band may be dimly visible. However, even in this case, if specific heat treatment or repeated heat treatment is executed, nucleation may be carried out and the O band may gradually become clearly visible.

The silicon wafer in accordance with the embodiment may have only an IDP region and a VDP region without the O band region shown in FIG. 3. Here, if the silicon wafer has a diameter of 300 mm, as described above, the IDP region may occupy 70% or more of the wafer. Further, in order to enlarge the IDP region in terms of crystal growth, the single crystal ingot growing apparatus 100 shown in FIG. 2 designs the heat shielding member 50 and controls convection of the molten liquid silicon 20 so as to enlarge a recombination section.

In terms of crystal growth, the above-described transition region may be manufactured through expansion of a length section of a temperature region (1250° C. to 1420° C.) in which the IDP region is formed.

A silicon wafer having the above-described transition region and the oxygen concentration difference ΔOi of 0.5 ppma or less may be manufactured by the single crystal ingot growing apparatus 100 shown in FIG. 2, as below.

With reference to FIG. 2, the rotational angular velocity of the silicon single crystal ingot 30 is calculated. For this purpose, the rotational angular velocity calculation unit 92 may calculate the rotational angular velocity of the silicon single crystal ingot 30 using the rotating velocity of the ingot 30 supplied from the pulling unit 40 and the diameter of the ingot 30 supplied from the sensor 90.

Thereafter, the first comparison unit 94 compares the rotational angular velocity calculated by the rotational angular velocity calculation unit 92 with a target rotational angular velocity TSR and outputs a result of comparison to the flow velocity controller 96 as an angular velocity error value.

Thereafter, the flow velocity controller 96 reduces the flow velocity of the molten liquid silicon 20 at a part 34 of the growing silicon single crystal ingot 30, the diameter of which is sensed at the part 34, according to the angular velocity error value received from the first comparison unit 94. For this purpose, the flow velocity controller 96 may control the pulling unit 40 and/or the support shaft driving unit 16 so as to reduce the flow velocity. That is, the flow velocity controller 96 controls the rotating velocity of the ingot 30 through the pulling unit 40 and controls the rotating velocity of the crucible 10 through the support shaft driving unit 16. If it is judged that the measured rotational angular velocity is greater than the target rotational angular velocity TSR through the angular velocity error value, the flow velocity controller 96 reduces the flow velocity. If the part 34, the diameter of which is sensed, corresponds to a meniscus of the molten liquid silicon 20, the flow velocity of the molten liquid silicon 20 may be reduced and, thus, the flow of the meniscus may be stabilized.

Thereafter, the diameter sensing unit 90 may sense the diameter of the silicon crystal silicon ingot 30.

Thereafter, the second comparison unit 110 compares the diameter sensed by the diameter sensing unit 90 with a target diameter TD and outputs a result of comparison to the pulling unit 40 as a diameter error value.

Thereafter, the pulling unit 40 changes the pulling velocity of the growing silicon single crystal ingot 30 according to the diameter error value, and rotates and pulls the silicon single crystal ingot 30 at the changed pulling velocity. Therefore, the pulling velocity of the growing silicon single crystal ingot 30 may be adjusted according to the diameter error value.

In general, the pulling unit 40 controls the pulling velocity of the silicon single crystal ingot 30 according to the diameter sensed by the diameter sensing unit 90. For example, if the diameter of the ingot 30 sensed by the diameter sensing unit 90 is greater than the target diameter TD, the pulling unit 40 increases the pulling velocity of the ingot 30 in proportion to the difference between the actually measured diameter of the ingot 30 and the target diameter. However, if the diameter sensed by the diameter sensing unit 90 is less than the target diameter TD, the pulling unit 40 decreases the pulling velocity of the ingot 30 in proportion to the difference between the actually measured diameter of the ingot 30 and the target diameter. Here, the meniscus 34, at which the diameter of the ingot is sensed, may become unstable due to influence of a node generated when the ingot 30 is grown or the intensity of the flow velocity of the molten liquid silicon 20. Although the meniscus 34 is unstable, if the pulling velocity is adjusted by the diameter which is actually measured through the unstable meniscus 34, a fluctuation range of the pulling velocity deviating from a target trajectory of the pulling velocity within T(V/G) may be greatly increased. In this case, the frequency of an ingot 30 or a silicon wafer, which includes crystal defects of an OISF region (a region between the small void region and the O band region) or crystal defects of the I region and may thus be treated as a failure, may be increased.

Differently, after the flow of the meniscus 34 is stabilized, as described above, the diameter is accurately sensed by the diameter sensing unit 90 and the pulling velocity is adjusted based on the accurately sensed value. Therefore, the fluctuation range of the pulling velocity V deviating from the trajectory 320 of the target pulling velocity is reduced.

Further, with reference to FIG. 2, the first controller 120 determines the position 62 of a maximum heating part of the heater 60. Thereafter, the second controller 130 determines the position of a maximum Gauss plane (MGP) according to the determined position 62 of the maximum heating part of the heater 60 received from the first controller 120. Here, the MGP means a part in which the horizontal component of a magnetic field generated from the magnetic field applying unit 80 becomes maximal. The magnetic field applying unit 80 is thermally isolated from the heater 60 by the heat insulator 70. The heater 60 may uniformly generate heat in the upward and downward directions or adjust the amount of generated heat in the upward and downward directions. If the heater 60 uniformly generates heat in the upward and downward directions, the maximum heating part may be located at the center of the heater 60 or at a position slightly above the center. However, if the heater 60 adjusts the amount of generated heat in the upward and downward directions, the maximum heating part may be arbitrarily adjusted.

Thereafter, the second controller 130 controls the magnetic field applying unit 80 so as to apply a magnetic field to the crucible 10 so that the MGP is formed at the determined position.

Thereafter, when the position of the maximum heating part is changed, the position of the MGP is adjusted according to the changed position 62 of the maximum heating part. The first controller 120 may control the heater 60 so as to change the position 62 of the maximum heating part. If the heater 60 is moves, the position 62 of the maximum heating part may be changed. The second controller 130 confirms the changed position 62 of the maximum heating part through the first controller 120 and adjusts the position at which the MGP will be formed according to the changed position.

Thereafter, the second controller 130 controls the magnetic field applying unit 80 so as to form the MGP at the adjusted position, thus applying a magnetic field to the crucible 10.

In accordance with one embodiment, the MGP may be determined so as to be located at a position lower than the position 62 of the maximum heating part. For example, the MGP may be located at a position lower than the position 62 of the maximum heating part by 20% to 40% based on the interface of the molten liquid silicon 20. That is, if the position 62 of the maximum heating part is separated from the interface of the molten liquid silicon 20 by a first distance D1, the MGP may be separated from the interface of the molten liquid silicon 20 by a second distance D2 which is lower than the first distance D1 by 20% to 40%. The second distance D2 may be 50 mm to 300 mm, for example, 150 mm.

Convection of the molten liquid silicon 20 may be controlled not only by adjusting the position 62 of the maximum heating part and the position of the MGP but also by the intensity of a magnetic field applied by the magnetic field applying unit 80.

In general, if the rotational angular velocity of the silicon single crystal ingot 30 is changed, a degree of convexness of the interface of the silicon liquid 20, a temperature gradient of the ingot 30 in the growing direction G=Gs+Gm [here, Gs represents a temperature gradient of the ingot and Gm represents a temperature gradient of the molten silicon liquid 20], a temperature gradient difference of the ingot 30 in the radial direction at a contact area between the ingot 30 and the molten silicon liquid 20 ΔG=Gse−Gsc [here, Gse and Gsc respectively represent temperature gradients of the edge and the center of the lower part of the ingot 30], a concentration of oxygen included in the ingot 30, and the size of a supercooled region formed between the ingot 30 and the molten silicon liquid 20 are changed. For example, when the rotational angular velocity of the silicon ingot 30 is increased, the interface of the molten silicon liquid 20 becomes very convex, a temperature gradient G is increased, a temperature gradient difference AG is decreased, an oxygen concentration is lowered and, thus, an ingot 30 having good quality may be generated but it is difficult to control the pulling velocity. On the contrary, when the rotational angular velocity of the silicon ingot 30 is decreased, the interface of the molten silicon liquid 20 becomes flat, a temperature gradient G is decreased, a temperature gradient difference AG is increased, an oxygen concentration is raised and, thus, an ingot 30 having poor quality may be generated but it is easy to control the pulling velocity. However, these relations may vary according to a magnetic field.

Further, in general, the molten liquid silicon 20 shown in FIG. 2 is convected in the direction of arrows 22 by rotation of the ingot 30 and convected in the direction of arrows 24 by rotation of the crucible 10. However, convection of the molten liquid silicon 20 may be blocked between the upper and lower parts thereof based on the MGP.

In accordance with this embodiment, the MGP may be determined in consideration of convection of the molten liquid silicon according to the position of the maximum heating part and convection of the molten liquid silicon 20 may be controlled by properly adjusting the intensity of the magnetic field, thereby compensating for problems caused by change of the rotational angular velocity. That is, when the MGP is located at a position separated from the interface of the molten liquid silicon 20 lower than the position 62 of the maximum heating part by 20% to 40%, convection toward the center of the ingot 30 in the direction of the arrows 22 becomes strong so that a recombination section between vacancies and interstitials may be secured and thus, the margin of the IDP region may be increased.

In this embodiment, in order to grow a silicon wafer or ingot including the transition region which dominantly has crystal defects having a size of 10 nm to 30 nm included in the IDP region and having an oxygen concentration difference ΔOi of 0.5 ppma or less, the apparatus shown in FIG. 2 is used. However, the above-described growing apparatus shown in FIG. 2 is only exemplary and, in order to execute respective operations, an Automatic Growing Controller (AGC) (not shown) or an Automatic Temperature Controller (ATC) (not shown) may be further used.

Further, in order to manufacture a silicon wafer in accordance with this embodiment, in addition to the rotational angular velocity of the silicon crystal silicon ingot 30, the MGP, the intensity of the magnetic field and the position of the maximum heating part, the pressure/flow rate of inert gas, such as Argon gas serving as cooling gas, a melt gap between the heat shielding member 50 and the interface of the molten liquid silicon 20, the shape of the heat shielding member 50, the number of heaters 60, and the rotating velocity of the crucible 10 may be further used also.

Hereinafter, characteristics of silicon wafers in accordance with embodiments will be described with reference to the accompanying drawings.

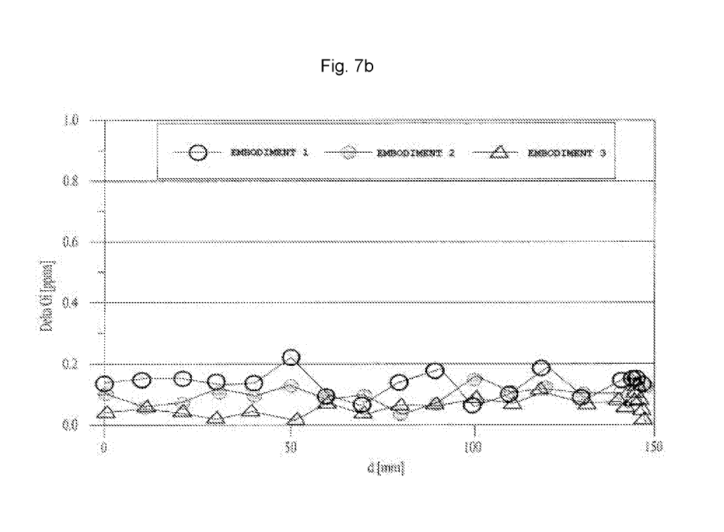

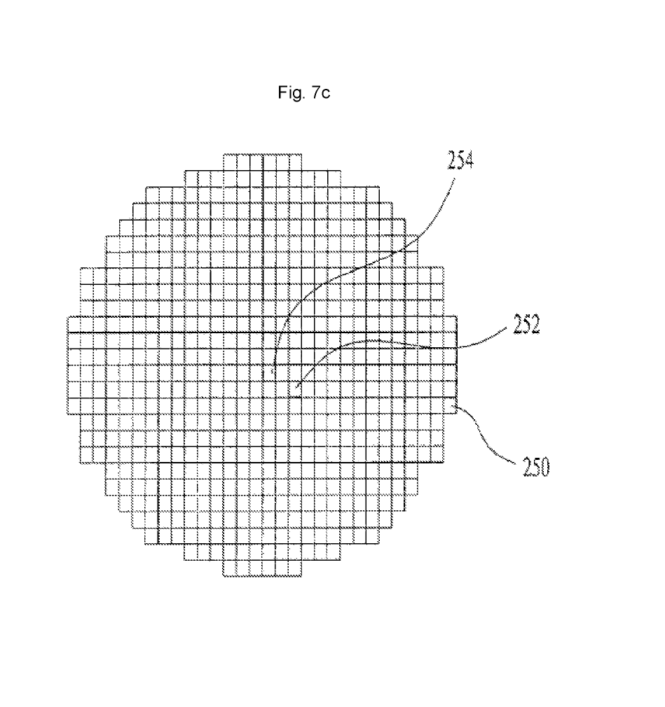

FIG. 7a is a graph representing initial oxygen concentrations of silicon wafers, FIG. 7b is a graph representing final oxygen concentrations of silicon wafers after heat treatment is repeated 6 times at a temperature of 1,000° C. for 1 hour, and FIG. 7c is a view illustrating Gate Oxide Integrity (GOI) after heat treatment has been executed. In FIGS. 7a and 7b, Embodiment 1 indicates a case wherein heat treatment is executed one time, Embodiment 2 indicates a case wherein heat treatment is executed two times, Embodiment 3 indicates a case wherein heat treatment is executed three times, and ‘d’ indicates a distance from the center of a wafer.

As exemplarily shown in FIG. 7a, when the level of the initial oxygen concentration of the silicon wafers is 10 ppma or less, oxygen concentration differences ΔOi in Embodiment 1 to Embodiment 3 are 0.2 ppma, as exemplarily shown in FIG. 7b. The reason for this is that, in the silicon wafer, crystal defects of the IDP region occupy 70% or more. If the silicon wafer does not include crystal defects of the IDP region of 70% or more but includes crystal defects of the O band and the VDP regions of 30% or more, oxygen concentration differences ΔOi of the silicon wafer are not 0.2 ppma or less and are thus not uniform, as in FIG. 7b. That is, the oxygen concentration difference ΔOi in the VDP region is greater than 0.5 ppma, the oxygen concentration difference ΔOi only in the IDP region is lowered, and uniformity of the oxygen concentration differences ΔOi of the wafer in the radial direction is not secured. This means that, if heat treatment is repeated, oxygen precipitates are generated in the VDP region.

As described above, it may be confirmed that, if heat treatment of a silicon wafer of the present invention is repeated, generation of oxygen precipitates is controlled. Further, as exemplarily shown in FIG. 7c, as a result of measurement of GOI after repeated heat treatment, it may be confirmed that failures 250, 252 and 254 due to crystal defects are reduced.

When a silicon wafer has a low initial oxygen concentration, as described above, it may be difficult to differentiate the IDP region and the VDP region, shown in FIG. 3, using a conventional crystal defect estimation method, for example, a Cu deposition method, [or a Cu Haze method] and the O band region may not be observed. For reference, the Cu deposition method is disclosed in Korean Patent Registration No. 10-0838350.

Therefore, if the silicon wafer has a low initial oxygen concentration as in the embodiments, the VDP region and the IDP region may be more clearly differentiated by a Ni haze method.

Hereinafter, the Ni haze method for differentiating a VDP region and an IDP region will be described with reference to the accompanying drawings.

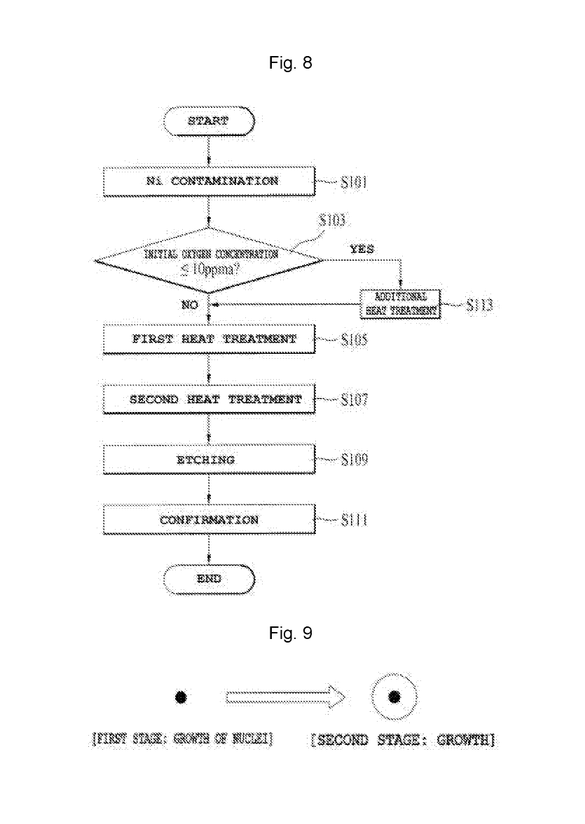

FIG. 8 is a flowchart illustrating the Ni haze method for differentiating defect regions of a silicon single crystal wafer in accordance with one embodiment.

The silicon single crystal wafer may be coated with a metal solution, such as Ni (Operation S101). Coating may be executed using a spin coating method or a dipping method but is not limited thereto.

When the silicon single crystal wafer is coated with Ni, the Ni solution may diffuse into the single crystal wafer and react with or be combined with oxygen precipitates, thus forming metal precipitates. Here, the concentration of Ni may be at least 1E13 atom/cm′ or more but is not limited thereto.

Ni may execute gettering of fine precipitates which may not be conventionally gettered by Cu, thus having better defect detection ability than Cu.

For example, if it is confirmed by using Ni that no defects are found from a silicon single crystal wafer, it may be more clearly confirmed than by using Cu the silicon single crystal wafer has no defects. Therefore, finer defects may be detected through the Ni haze method in accordance with the embodiment and a silicon single crystal wafer through growth of a good quality defect-free silicon ingot may be manufactured based on such a Ni haze method.

Further, a semiconductor device having more finely controlled defects may be manufactured using a defect-free silicon single crystal wafer.

It is judged whether or an initial oxygen concentration Oi is a critical value or less (Operation S103). For example, the critical value may be set to 10 ppma but is not limited thereto.

If the initial oxygen concentration Oi is not the critical value or less, first heat treatment may be executed (Operation S105). The first heat treatment may serve to nucleate the metal precipitates. For example, the first heat treatment may be executed for 4 hours at a heat treatment temperature of 870° C. Nuclei of the metal precipitates may be formed by the first heat treatment. Such nuclei of the metal precipitates may be used as seeds for growth of the nuclei of the metal precipitates due to a subsequent process, i.e., second heat treatment.

When the nuclei of the metal precipitates are formed by the first heat treatment, second heat treatment may be executed (Operation S107). The second heat treatment may serve to grow the nuclei of the metal precipitates so as to increase the size of the metal precipitates using the nuclei of the metal precipitates as seeds. The metal precipitates may be grown from the nuclei in all directions by the second heat treatment but are not limited thereto. For example, the second heat treatment may be executed for 1 to 3 hours at a heat treatment temperature of 1000° C.

As exemplarily shown in FIG. 9, since the nuclei of the metal precipitates are formed by the first heat treatment (Operation S105) and are grown using the nuclei as seeds by the second heat treatment (Operation S107), the size of the metal precipitates may be increased.

As the size of the metal precipitates is increased, a detection probability of the metal precipitates in a confirmation operation, which will be described later, may be increased.

When the initial oxygen concentration Oi is excessively low, detection of metal precipitates by Ni contamination may not be easy. In this case, additional heat treatment may be executed (Operation S113). The additional heat treatment may be executed for 4 hours at a heat treatment temperature of 800° C. The additional heat treatment may serve to enlarge the size of the metal precipitates. Although the initial oxygen concentration Oi is excessively low, the size of the metal precipitates may be enlarged by the additional heat treatment and the enlarged metal precipitates may be additionally enlarged by two-stage heat treatment of Operations S105 and S107, i.e., the first heat treatment and the second treatment.

In the Ni haze method in accordance with the embodiment, even if the initial oxygen concentration Oi is low, defects may be more finely detected using a similar method to the case in that the initial oxygen concentration Oi is high.

Thereafter, etching of the silicon single crystal wafer may be executed (Operation S109). Here, etching may be wet etching. A mixture of nitric acid (HNO₃) and hydrofluoric acid (HF) may be used as an etching solution, but the disclosure is not limited thereto. Etching in Operation S109 serves to more easily detect defects and, if the concentration and size of the metal precipitates are critical values or more, etching in Operation S109 may be omitted.

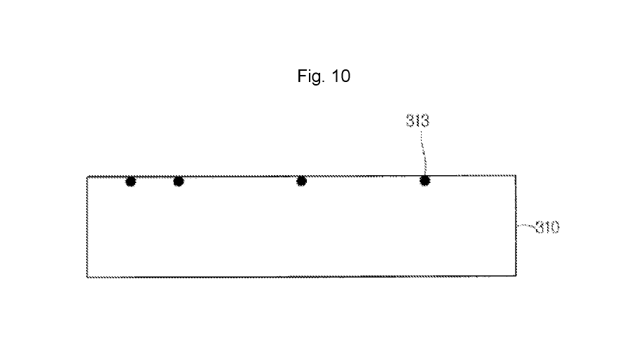

As exemplarily shown in FIG. 10, metal precipitates 313 may be formed on the surface of a silicon single crystal wafer 310 by Operations S101 to S107.

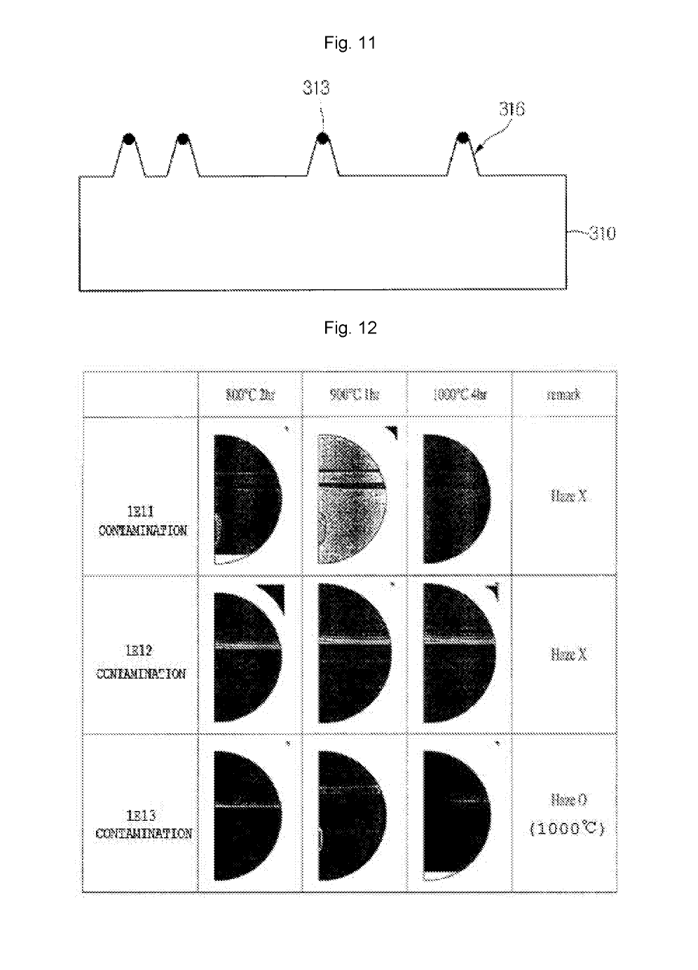

As exemplarily shown in FIG. 11, the surface of the silicon single crystal wafer 310 except for the metal precipitates 310 may be etched through etching in Operation S109. In this case, conical protrusions 316 may be formed under the metal precipitates 313. That is, the protrusions 316 may be formed under the metal precipitates 313 and the surface of the silicon single crystal wafer 310 except for the metal precipitates 313 may be etched. In this case, there is a height difference between a region in which the metal precipitates 313 are present on the surface of the silicon single crystal wafer and a region in which no metal precipitate 313 are present on the surface of the silicon single crystal wafer and an optical path of a detection device (not shown) is changed by the height difference. Therefore, the metal precipitates 313 may be more clearly visible in an image generated by the detection device due to an optical path difference and the metal precipitates 313 may be more easily detected.

As exemplarily shown in FIG. 12, it may be confirmed that, if a Ni concentration is 1E11 atom/cm² or 1E12 atom/cm², no metal precipitates are detected although the temperature and time of heat treatment are varied.

On the other hand, if a Ni concentration is 1E13 atom/cm², metal precipitates may be detected. Therefore, the Ni concentration may preferably be at least 1E13 atom/cm².

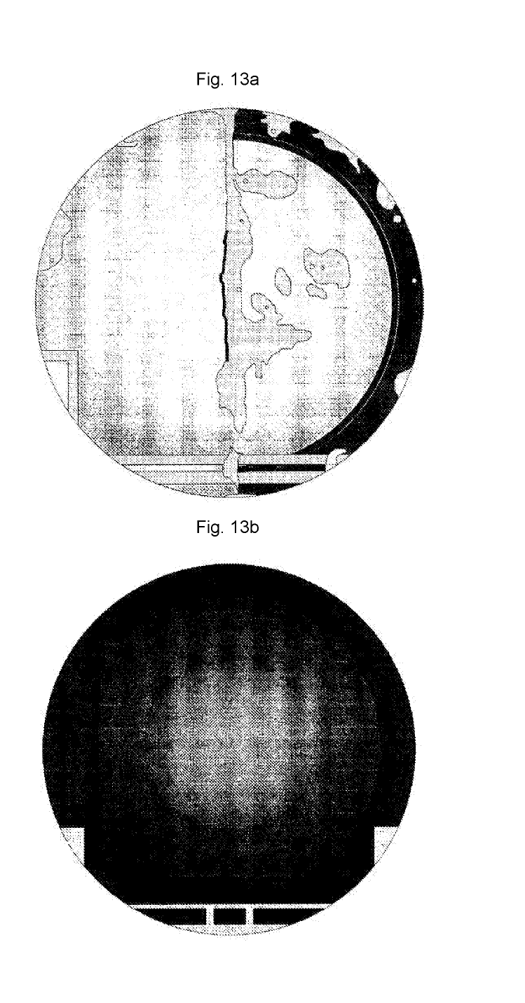

FIG. 13a is a view illustrating a surface state of a silicon single crystal wafer if Cu contamination is used and FIG. 13b is a view illustrating a surface state of a silicon single crystal wafer if Ni contamination is used.

As exemplarily shown in FIG. 13a, if Cu contamination is used, the silicon single crystal wafer does not show a defect haze.

On the other hand, as exemplarily shown in FIG. 13b, if Ni contamination is used, the silicon single crystal wafer clearly shows a defect haze.

Therefore, the Ni haze method for differentiating defect regions of a silicon single crystal wafer in accordance with the embodiment may detect defects which are not detected through the Cu haze method.

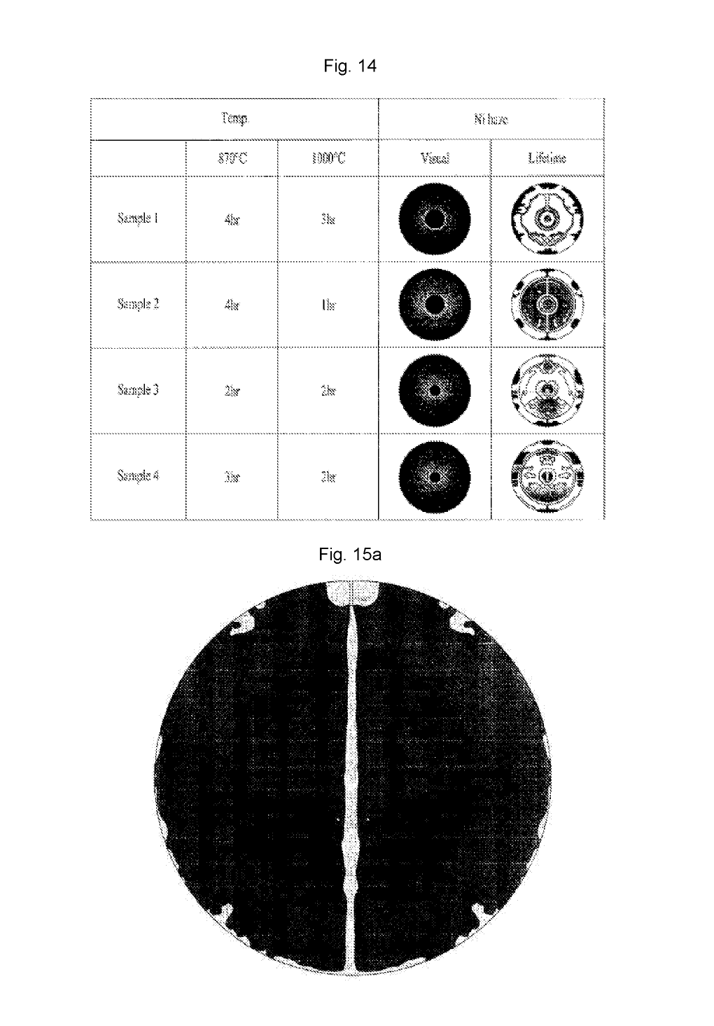

FIG. 14 is a table illustrating test results of the optimum conditions of two-stage heat treatment.

As exemplarily shown in FIG. 14, in the first heat treatment, the heat treatment temperature is fixed to 870° C. but the heat treatment time is varied to 2 hours, 3 hours and 4 hours. In the second heat treatment, the heat treatment temperature is fixed to 1000° C. but the heat treatment time is varied to 1 hour, 2 hours and 3 hours.

Sample 3 and Sample 4 do not clearly show a defect haze. On the other hand, Sample 1 and Sample 2 clearly show a defect haze.

Therefore, in the Ni haze method in accordance with the embodiment, it may be understood that, in the case of the first heat treatment having a heat treatment temperature of 870° C. and a heat treatment time of 4 hours and the heat treatment having a heat treatment temperature of 1000° C. and a heat treatment time of 1 hour to 3 hours, good defect hazes are acquired.

Confirmation of metal precipitates on the silicon single crystal wafer, on which etching has been completed, may be executed (Operation S111).

The metal precipitates may be confirmed from an image acquired by, for example, a camera but the disclosure is not limited thereto. Further, the metal precipitates may be confirmed by, for example, an optical microscope but the disclosure is not limited thereto.

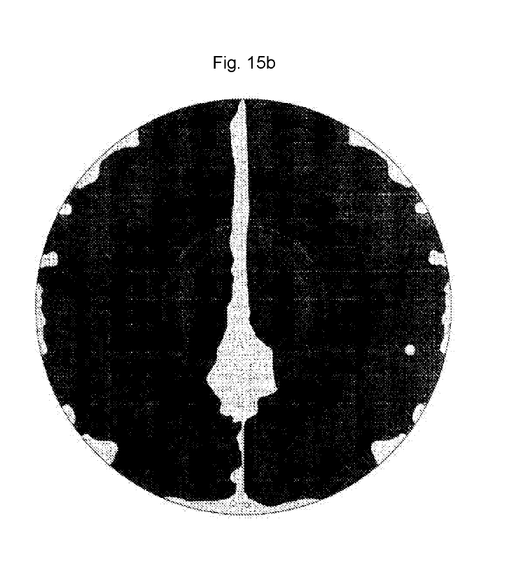

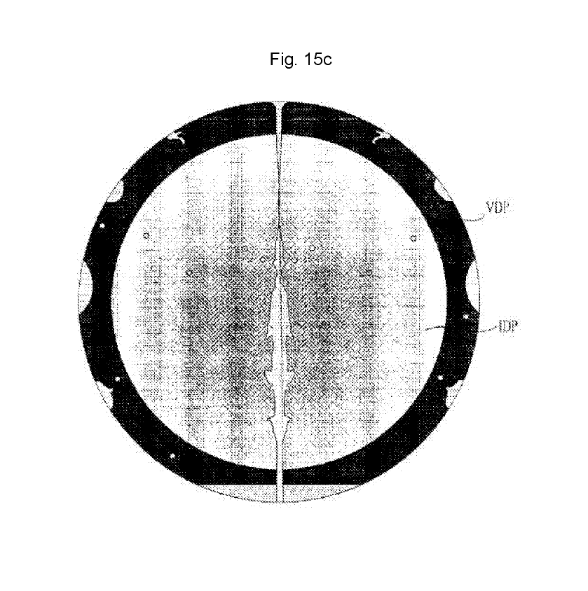

FIGS. 15a to 15c are views illustrating distributions of defects according to oxygen concentrations based on Cu. For example, the initial oxygen concentration Oi of FIG. 15a is 8.3 ppma, the initial oxygen concentration Oi of FIG. 15b is 9.5 ppma, and the initial oxygen concentration Oi of FIG. 15c is 10.8 ppma.

If defects are detected using the Cu haze method, an IDP region and a VDP region are not clearly differentiated at the initial oxygen concentration of 8.3 ppma (in FIG. 15a) or 9.5 ppma (in FIG. 15b). At the initial oxygen concentration of 10.8 ppma, an IDP region and a VDP region may be differentiated.

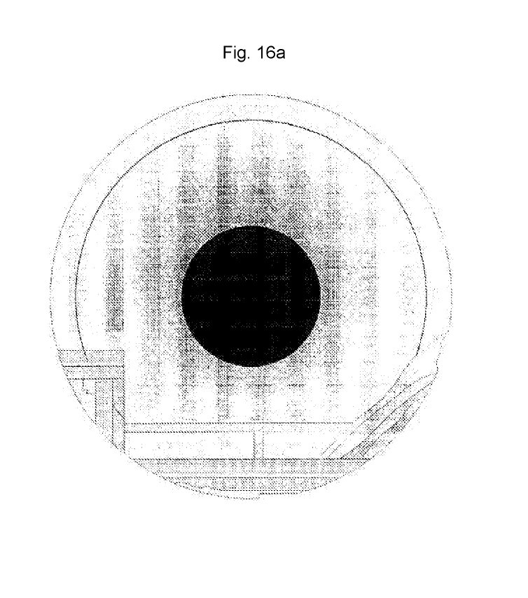

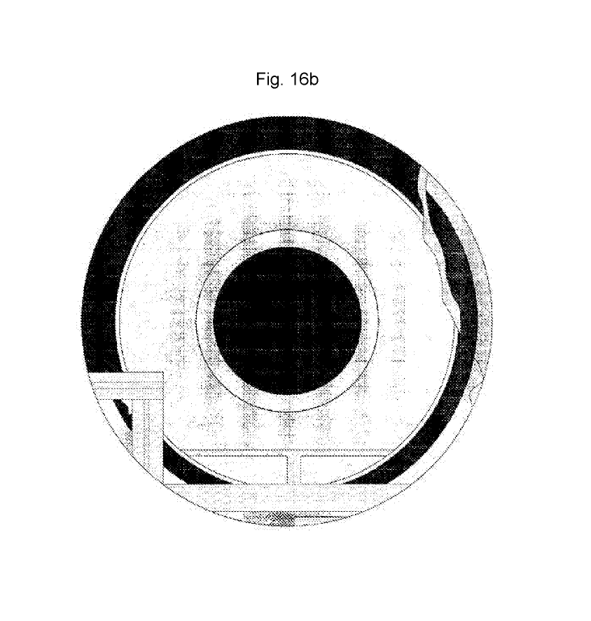

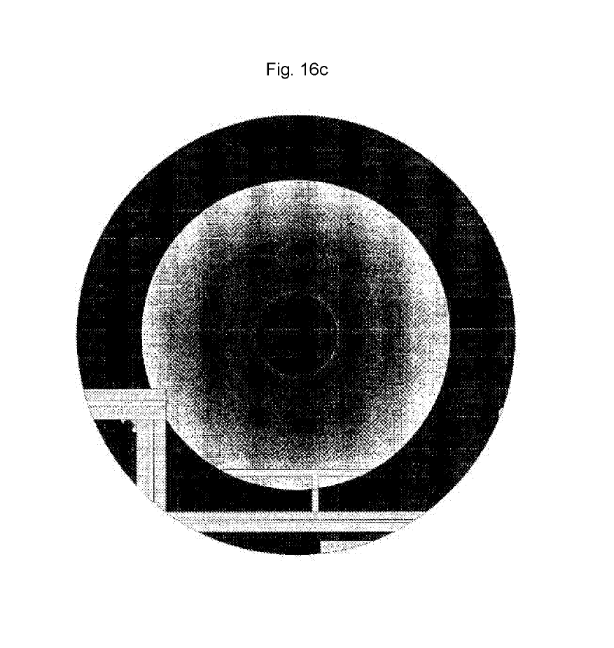

FIGS. 16a to 16c are views illustrating distributions of defects according to oxygen concentrations based on the Ni haze method. For example, the initial oxygen concentration Oi of FIG. 16a is 8.3 ppma, the initial oxygen concentration Oi of FIG. 16b is 9.5 ppma, and the initial oxygen concentration Oi of FIG. 16c is 10.8 ppma.

If defects are detected using the Ni haze method, an IDP region and a VDP region may be differentiated at the initial oxygen concentration of 8.3 ppma (in FIG. 16a), 9.5 ppma (in FIG. 16b) or 10.8 ppma (in FIG. 16c).

The VDP region may be a region in which oxygen precipitates are present and the IDP region may be a region in which no oxygen precipitates are present.

In FIG. 15c, the entirety of the central region of the silicon single crystal wafer is the IDP region but, in FIG. 16c, the centermost region of the central region of the silicon single crystal wafer may be defined as the VDP region and the circumference of the centermost region may be defined as the IDP region.

Thereby, if defects are detected using the Cu haze method (in FIG. 15c), the VDP region present at the central region may not be detected but, if defects are detected using the Ni haze method (in FIG. 16c), the VDP region present at the central region may be detected. That is, if defects are detected using the Cu haze method (in FIG. 15c), although defects are present in the central region, the IDP region without defects may be detected. On the other hand, if defects are detected using the Ni haze method (in FIG. 16c), defects present in the central region may be accurately detected as the VDP region.

Therefore, it may be confirmed from FIGS. 15a to 16c that defects may be more accurately detected through defect detection using the Ni haze method rather than defect detection using the Cu haze method.

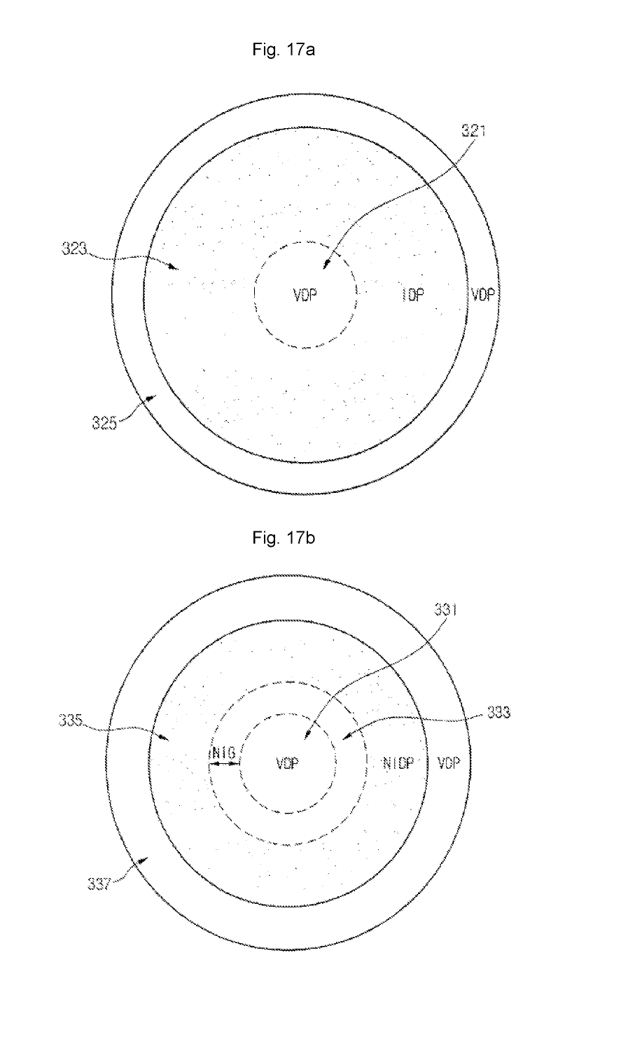

FIG. 17a is a view illustrating division of regions defined in a silicon single crystal wafer through the Cu haze method, and FIG. 17b is a view illustrating division of regions defined in a silicon single crystal wafer through the Ni haze method.

As exemplarily shown in FIG. 17a, a first region 321 and a third region 325 are VDP regions and a second region 323 is an IDP region. The second region 323 may be disposed between the first region 321 and the third region 325.

As described above, the VDP region may mean a region in which defects are present and the IDP region may mean a region in which no defects are present.

As exemplarily shown in FIG. 17b, a first region 331 and a fourth region 337 may be VDP regions, a second region 333 may be a Ni gettering (NiG) region, and a third region 335 is a Ni based IDP (NIDP) region.

As described above, the VDP region is a region in which defects are present.

The NiG region 333 may be defined as a region in which defects are not detected based on Cu but defects are detected only based on Ni.

The NIDP region 335 may be defined as a region in which no defects are present based on Ni, i.e., a pure defect-free region.

Therefore, defects, such as oxygen precipitates, are less present in the Ni-based NIDP region (in FIG. 17b), as compared to the Cu-based VDP region (in FIG. 17a). By manufacturing a silicon single crystal wafer in the Ni-based NIDP region, a semiconductor device having more finely controlled defects may be manufactured so as to cope with customer requirements.

Defects in the VDP region may be detected by the Cu haze method. Differently from FIG. 3, it may be defined the NiG region and the NIDP region are disposed between the VDP region and the I region.

Defects in the NiG region are not detected by the Cu haze method but may be detected only by the Ni haze method. Therefore, defects in the NiG region as well as defects in the VDP region may be detected based on Ni. The NiG region may be included in the VDP region of FIG. 3.

The NIDP region is a region in which high defects are not detected based on Ni and may thus be defined as a pure defect-free region corresponding to the DIP region of FIG. 3.

The pulling velocity V of the NiG region may be between the pulling velocity of the VDP region and the pulling velocity of the NIDP region. That is, the pulling velocity V of the NiG region may be less than the pulling velocity of the VDP region and greater than the pulling velocity of the NIDP region but the disclosure is not limited thereto.

In the case of the silicon wafer in accordance with the above-described embodiment, since the IDP region occupies 70% or more of the entire transition region and the oxygen concentration difference ΔOi is 0.5 ppma or less, generation of oxygen precipitates may be suppressed.

Therefore, in the case of a conventional silicon wafer, an initial oxygen concentration needs to be lowered to 5 ppma or less due to generation of oxygen precipitates but, in the case of the silicon wafer in accordance with the embodiment, the IDP region is dominant and, even if an initial oxygen concentration is relatively high, i.e., 10 ppma, a wafer for SOI may be manufactured.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. For example, various variations and modifications are possible in the component parts of these embodiments. Further, those skilled in the art will appreciate that differences related to these variations and modifications are within the scope of the disclosure, defined as disclosed in the accompanying claims.

### INDUSTRIAL APPLICABILITY

The embodiments may be applied to manufacture a silicon single crystal ingot for semiconductors and to manufacture a wafer from the ingot.

1. A silicon single crystal ingot and wafer for semiconductors, comprising a transition region which dominantly has crystal defects having a size of 10 nm to 30 nm, among crystal defects included in an interstitial dominant defect-free region, wherein a difference between an initial oxygen concentration before heat treatment of the ingot and wafer is executed at least one time and a final oxygen concentration after heat treatment of the ingot and wafer has been executed at least one time is 0.5 ppma or less.

2. The silicon single crystal ingot and wafer for semiconductors according to claim 1, wherein the transition region further includes a vacancy dominant defect-free region,
wherein the interstitial dominant defect-free region occupies 70% or more of the entire transition region based on a diameter of the wafer.

3. The silicon single crystal ingot and wafer for semiconductors according to claim 1, wherein, among entire crystal defects included in the transition region, the crystal defects having a size of 10 nm to 30 nm are more than 50%.

4. The silicon single crystal ingot and wafer for semiconductors according to claim 1, wherein, among entire crystal defects included in the transition region, the crystal defects having a size of 10 nm to 30 nm are more than 70%.

5. The silicon single crystal ingot and wafer for semiconductors according to claim 1, wherein the size of the crystal defects included in the transition region is 10 nm to 19 nm.

6. The silicon single crystal ingot and wafer for semiconductors according to claim 2, wherein the vacancy dominant defect-free region and the interstitial dominant defect-free region are differentiable by a Ni haze method.

7. The silicon single crystal ingot and wafer for semiconductors according to claim 1, wherein the execution of heat treatment at least one time includes repetition of heat treatment 6 times or more.

8. The silicon single crystal ingot and wafer for semiconductors according to claim 7, wherein the wafer is a wafer for SOI.

9. The silicon single crystal ingot and wafer for semiconductors according to claim 1, wherein the initial oxygen concentration is 10 ppma or less.

10. The silicon single crystal ingot and wafer for semiconductors according to claim 1, wherein the transition region does not include crystal defects belonging to an O band region.

11. The silicon single crystal ingot and wafer for semiconductors according to claim 1, wherein the transition region includes crystal defects, belonging to an O band region, at an amount of 30% or less.

12. The silicon single crystal ingot and wafer for semiconductors according to claim 1, wherein the transition region further includes an O band region and a vacancy dominant defect-free region, and
wherein the O band and vacancy dominant defect-free regions occupy less than 30% of the entire transition region based on a diameter of the wafer.

13. The silicon single crystal ingot and wafer for semiconductor according to claim 2, wherein, the vacancy dominant defect-free region is located at an edge of the wafer, and
wherein the interstitial dominant defect-free region is located at a center inside the edge of the wafer.

14. A single crystal ingot growing apparatus for growing the silicon single crystal ingot according to claim 1, the apparatus comprising:
a crucible containing a molten liquid silicon;
a heater heating the crucible;
a magnetic field applying unit applying a magnetic field to the crucible; and
a controller controlling the heater and the magnetic field applying unit, to locate a MGP at a position lower than a position of a maximum heating part by 20% to 40% based on an interface of the molten liquid silicon.
